(19) United States
(12) Patent Application Publication
(10) Pub. No.: US 2015/0016062 A1
(43) Pub. Date: Jan. 15, 2015

(54) HIGHLY INTEGRATED POWER ELECTRONIC MODULE ASSEMBLY

(71) Applicant: Ford Global Technologies, LLC, Dearborn, MI (US)

(72) Inventor: Brian Joseph Robert, St. Clair Shores, MI (US)

(21) Appl. No.: 13/940,836

(22) Filed: Jul. 12, 2013

(51) Int. Cl. H05K 7/20

(52) U.S. Cl. CPC H05K 7/2029
USPC 361/700; 29/592.1

(57) ABSTRACT

A power electronic module assembly according to an exemplary aspect of the present disclosure includes, among other things, a vapor chamber and a substrate integrated with a first surface of the vapor chamber. At least one cooling feature is integrated with a second surface of the vapor chamber.

### TECHNICAL FIELD

This disclosure relates to power electronic systems, and more particularly, but not exclusively, to a highly integrated power electronic module assembly that employs a vapor chamber.

### BACKGROUND

Power electronic systems supply power in a variety of modem devices. For example, power electronic systems may output power in computers, vehicles, lighting and many other devices.

Power electronic systems typically employ power electronic module assemblies for supplying electrical power. In general, the amount of heat generated by power electronic module assemblies increases with increased power output of the device. Therefore, thermal management of the heat generated by the power electronic module assembly may become necessary.

### SUMMARY

A power electronic module assembly according to an exemplary aspect of the present disclosure includes, among other things, a vapor chamber and a substrate integrated with a first surface of the vapor chamber. At least one cooling feature is integrated with a second surface of the vapor chamber.

In a further non-limiting embodiment of the foregoing assembly, the power electronic module assembly excludes bonding or interface layers between the vapor chamber and each of the substrate and the at least one cooling feature.

In a further non-limiting embodiment of either of the foregoing assemblies, the substrate is an insulated metal substrate (IMS).

In a further non-limiting embodiment of any of the foregoing assemblies, the substrate includes at least one metal layer and at least one dielectric layer.

In a further non-limiting embodiment of any of the foregoing assemblies, the first surface is a top surface of the vapor chamber and the second surface is a bottom surface of the vapor chamber.

In a further non-limiting embodiment of any of the foregoing assemblies, a heat source device is mounted to the substrate.

In a further non-limiting embodiment of any of the foregoing assemblies, the substrate is direct bonded to the first surface.

In a further non-limiting embodiment of any of the foregoing assemblies, the substrate is integrated onto the first surface by direct deposition.

In a further non-limiting embodiment of any of the foregoing assemblies, the substrate is integrated at least partially inside of the vapor chamber.

In a further non-limiting embodiment of any of the foregoing assemblies, the at least one cooling feature includes fins or pins.

A vehicle according to an exemplary aspect of the present disclosure includes, among other things, a controller and a power electronic module assembly housed by the controller and having a vapor chamber and a substrate integrated with the vapor chamber.

In a further non-limiting embodiment of the foregoing vehicle, the controller is an inverter system controller.

In a further non-limiting embodiment of either of the foregoing vehicles, the controller is a converter system controller.

In a further non-limiting embodiment of any of the foregoing vehicles, the controller is an inverter system controller combined with a variable voltage converter.

In a further non-limiting embodiment of any of the foregoing vehicles, a cooling feature is integrated with the vapor chamber opposite from the substrate.

A method for providing a highly integrated power electronic module assembly according to another exemplary aspect of the present disclosure includes, among other things, employing a vapor chamber and integrating a substrate with a first surface of the vapor chamber.

In a further non-limiting embodiment of the foregoing method, the method includes direct bonding the substrate on the first surface.

In a further non-limiting embodiment of either of the foregoing methods, the method includes direct depositing the substrate on the first surface.

In a further non-limiting embodiment of any of the foregoing methods, the method includes enveloping the substrate at least partially inside the vapor chamber.

In a further non-limiting embodiment of any of the foregoing methods, the method includes integrating at least one cooling feature onto a second surface of the vapor chamber.

The various features and advantages of this disclosure will become apparent to those skilled in the art from the following detailed description. The drawings that accompany the detailed description can be briefly described as follows.

### BRIEF DESCRIPTION OF THE DRAWINGS

FIG. 1 schematically illustrates a powertrain of a vehicle.

FIG. 2 illustrates an exemplary power electronic module assembly.

FIG. 3 illustrates a vapor chamber of the power electronic module assembly of FIG. 2.

FIGS. 4A, 4B and 4C illustrate various cooling features that may be incorporated into a power electronic module assembly.

FIG. 5 illustrates another exemplary power electronic module assembly.

FIG. 6 illustrates yet another power electronic module assembly.

### DETAILED DESCRIPTION

This disclosure relates to a highly integrated power electronic module assembly for enhanced thermal performance. The power electronic module assembly of this disclosure employs a vapor chamber as a passive, high efficiency heat spreader. The vertical footprint of the assembly is reduced by integrating a substrate and a cooling feature on or into the vapor chamber. The reduced vertical footprint may also result in a reduction of the heat source-to-coolant thermal resistance of the assembly, thereby improving thermal uniformity and performance.

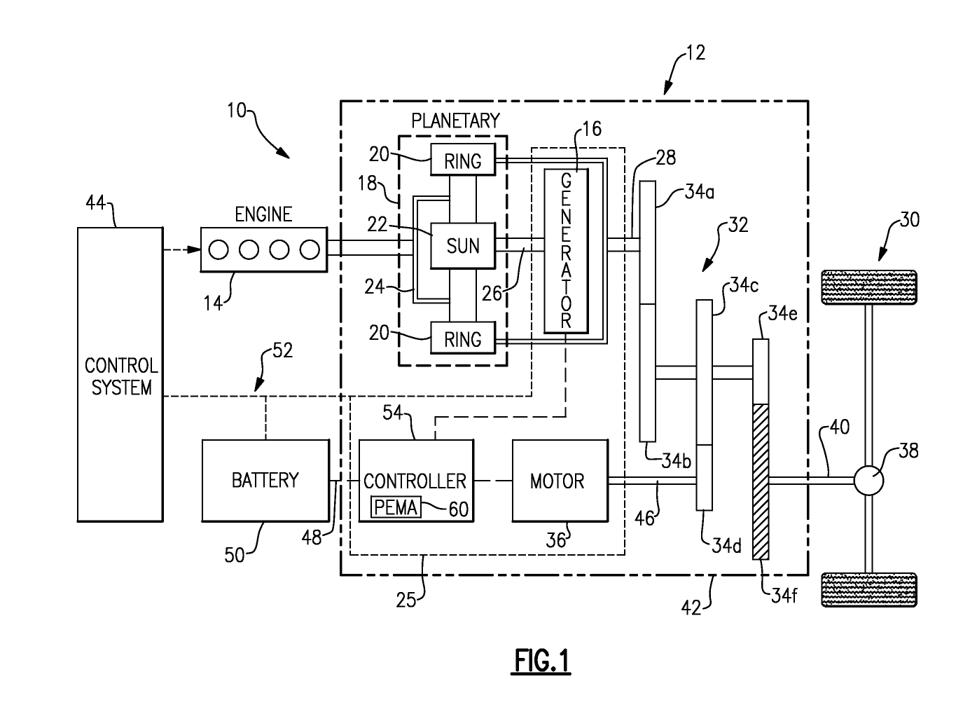

FIG. 1 schematically illustrates a powertrain 10 for a vehicle 12. In one embodiment, the vehicle 12 is a hybrid electric vehicle (HEV). Although depicted as a HEV, it should be understood that the concepts described herein are not limited to HEV's and could extend to other electric vehicles, including but not limited to, plug-in hybrid electric vehicles (PHEV's) and battery electric vehicles (BEV's). The teachings of this disclosure may also be applicable to conventional motor vehicles.

In one embodiment, the powertrain 10 is a powersplit powertrain system that employs a first drive system that includes a combination of an engine 14 and a generator 16 (i.e., a first electric machine) and a second drive system that includes at least a motor 36 (i.e., a second electric machine), the generator 16 and a battery 50. For example, the motor 36, the generator 16 and the battery 50 may make up an electric drive system 25 of the powertrain 10. The first and second drive systems generate torque to drive one or more sets of vehicle drive wheels 30 of the vehicle 12, as discussed in greater detail below.

The engine 14, such as an internal combustion engine, and the generator 16 may be connected through a power transfer unit 18. In one non-limiting embodiment, the power transfer unit 18 is a planetary gear set. Of course, other types of power transfer units, including other gear sets and transmissions, may be used to connect the engine 14 to the generator 16. The power transfer unit 18 may include a ring gear 20, a sun gear 22 and a carrier assembly 24. The generator 16 is driven by the power transfer unit 18 when acting as a generator to convert kinetic energy to electrical energy. The generator 16 can alternatively function as a motor to convert electrical energy into kinetic energy, thereby outputting torque to a shaft 26 connected to the carrier assembly 24 of the power transfer unit 18. Because the generator 16 is operatively connected to the engine 14, the speed of the engine 14 can be controlled by the generator 16.

The ring gear 20 of the power transfer unit 18 may be connected to a shaft 28 that is connected to vehicle drive wheels 30 through a second power transfer unit 32. The second power transfer unit 32 may include a gear set having a plurality of gears 34A, 34B, 34C, 34D, 34E, and 34F. Other power transfer units may also be suitable. The gears 34A-34F transfer torque from the engine 14 to a differential 38 to provide traction to the vehicle drive wheels 30. The differential 38 may include a plurality of gears that enable the transfer of torque to the vehicle drive wheels 30. The second power transfer unit 32 is mechanically coupled to an axle 40 through the differential 38 to distribute torque to the vehicle drive wheels 30.

The motor 36 can also be employed to drive the vehicle drive wheels 30 by outputting torque to a shaft 46 that is also connected to the second power transfer unit 32. In one embodiment, the motor 36 and the generator 16 are part of a regenerative braking system in which both the motor 36 and the generator 16 can be employed as motors to output torque. For example, the motor 36 and the generator 16 can each output electrical power to a high voltage bus 48 and the battery 50. The battery 50 may be a high voltage battery that is capable of outputting electrical power to operate the motor 36 and the generator 16. Other types of energy storage devices and/or output devices can also be incorporated for use with the vehicle 12.

The motor 36, the generator 16, the power transfer unit 18, and the power transfer unit 32 may generally be referred to as a transaxle 42, or transmission, of the vehicle 12. Thus, when a driver selects a particular shift position, the transaxle 42 is appropriately controlled to provide the corresponding gear for advancing the vehicle 12 by providing traction to the vehicle drive wheels 30.

The powertrain 10 may additionally include a control system 44 for monitoring and/or controlling various aspects of the vehicle 12. For example, the control system 44 may communicate with the electric drive system 25, the power transfer units 18, 32 or other components to monitor and/or control the vehicle 12. The control system 44 includes electronics and/or software to perform the necessary control functions for operating the vehicle 12. In one embodiment, the control system 44 is a combination vehicle system controller and powertrain control module (VSC/PCM). Although it is shown as a single hardware device, the control system 44 may include multiple controllers in the form of multiple hardware devices, or multiple software controllers within one or more hardware devices.

A controller area network (CAN) 52 allows the control system 44 to communicate with the transaxle 42. For example, the control system 44 may receive signals from the transaxle 42 to indicate whether a transition between shift positions is occurring. The control system 44 may also communicate with a battery control module of the battery 50, or other control devices.

Additionally, the electric drive system 25 may include one or more controllers 54, such as an inverter system controller (ISC). The controller 54 is configured to control specific components within the transaxle 42, such as the generator 16 and/or the motor 36, such as for supporting bidirectional power flow. In another embodiment, the controller 54 is a converter system controller. In yet another embodiment, the controller 54 is an inverter system controller combined with a variable voltage converter (ISC/VVC).

The controller 54 may house and employ one or more power electronic module assemblies 60 (labeled PEMA in FIG. 1) as part of a power electronic system of the vehicle 12. A relatively significant amount of heat flux may be generated within each power electronic module assembly 60 when supplying power to various loads throughout the vehicle 12. As discussed in detail below, the power electronic module assemblies 60 of the vehicle 12 may incorporate various features designed to thermally manage this heat flux.

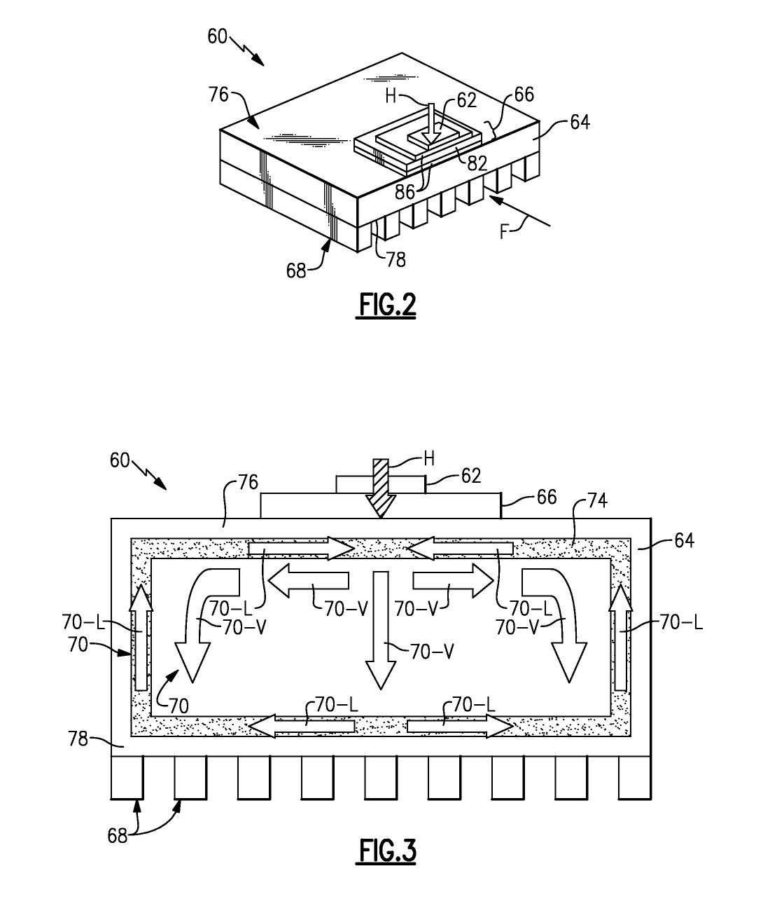

FIG. 2 illustrates an exemplary power electronic module assembly 60 that may be employed within a vehicle, such as the vehicle 12 of FIG. 1. In one embodiment, the power electronic module assembly 60 is part of an inverter system controller of the vehicle 12. In another embodiment, the power electronic module assembly 60 is part of a converter system controller of the vehicle 12. In yet another embodiment, the power electronic module assembly 60 is part of an inverter system controller combined with a variable voltage converter. It should be appreciated that the power electronic module assembly 60 can be implemented in any power electronic system for any application.

The exemplary power electronic module assembly 60 includes at least a heat source device 62, a vapor chamber 64, a substrate 66 and a cooling feature 68. Of course, this view is a highly schematic, cut-away view and may only illustrate portions of a power electronic module assembly. In other words, the power electronic module assembly 60 may include other components, connectors and/or features and this disclosure is not limited to the specific configuration shown.

In one embodiment, the heat source device 62 is a semiconductor device (e.g., transistor (MOSFET, IGBT), diode, etc.). During operation of a power electronic system, the heat source device 62 processes power, such as for supplying the propulsion power to the vehicle 12. This power processing creates heat H that may need dissipated from the power electronic module assembly 60. Although only one is shown, the power electronic module assembly 60 could include multiple heat source devices 62.

The power electronic module assembly 60 employs the vapor chamber 64 as a passive, high efficiency heat spreader for dissipating the heat H generated by the heat source device 62. The vapor chamber 64 is considered passive as it requires no moving components or external power for its operation. The vapor chamber 64 distributes or spreads the heat H generated by the heat source device 62 over an increased surface area that extends across the various parts of the power electronic module assembly 60. In one embodiment, as discussed in greater detail with reference to FIG. 3, the vapor chamber 64 relies on thermal conductivity and phase transition to thermally manage the heat H generated by the heat source device 62.

The vapor chamber 64 includes a first surface 76 and a second surface 78 opposite the first surface 76. In one embodiment, the first surface 76 is a top face and the second surface 78 is a bottom face of the vapor chamber 64. However, the first and second surfaces 76, 78 may be disposed elsewhere on the vapor chamber 64.

The substrate 66 is positioned between the heat source device 62 and the vapor chamber 64. The substrate 66 dissipates the heat H from the heat source device 62 into the vapor chamber 64. In one embodiment, the substrate 66 includes an insulated metal substrate (IMS). The substrate 66 may include alternating layers of a metal layer 80 and a dielectric layer 82. In this embodiment, the dielectric layer 82 is sandwiched between two metal layers 80. However, other configurations are contemplated, including configurations having fewer or additional layers of both metals and dielectrics. In one non-limiting embodiment, the metal layers 80 are made of aluminum or copper and the dielectric layers 82 are made of a ceramic, such as Al₂O₃, AlN, or Si₃N₄, or an epoxy.

In one embodiment, the substrate 66 is integrated with the first surface 76 of the vapor chamber 64. In this disclosure, the term “integrated” denotes an interface between adjacent components of the power electronic module assembly 60 that excludes bonding or interface layers such as solder, thermal grease, or other layers. Integrating the substrate 66 on or into the vapor chamber 64 reduces the vertical footprint of the power electronic module assembly 60. Moreover, the reduced vertical footprint may result in a reduction of the thermal resistance of the power electronic module assembly 60, thereby improving thermal uniformity and performance.

In one embodiment, the substrate 66 is direct bonded to the vapor chamber 64. The substrate 66 may be direct bonded on the first surface 76 of the vapor chamber 64. As used in this disclosure, the term “direct bonding” refers to methods to affix two surfaces to one another with limited to no interface layers. Suitable direct bonding processes include, but are not limited to, brazing, sintering, diffusion bonding, transient liquid phase (TLP) bonding, etc.

The cooling feature 68 may be integrated with the second surface 78 of the vapor chamber 64. The cooling feature 68 dissipates heat away from the vapor chamber 64. For example, the cooling feature 68 provides extended surfaces for transferring heat between the vapor chamber 64 and a surrounding fluid F (such as a gas or liquid coolant). Like the substrate 66, the cooling feature 68 is integrated with the vapor chamber 64 without the use of interfacing layers such as solder, adhesives, thermal grease, thermal pastes, or the like. Cooling feature 68 integration methods can be performed via mechanical (stamping, machining, etc.), chemical (wet etching, plating), and other bonding/deposition techniques such as those described herein. Integration of the cooling feature 68 onto the second surface 78 of the vapor chamber 64 further reduces the vertical footprint, thereby reducing package size while simultaneously improving thermal management of the power electronic module assembly 60. Moreover, the reduced vertical footprint may result in a reduction of the thermal resistance of the power electronic module assembly 60, thereby improving thermal uniformity and performance.

FIG. 3 illustrates one embodiment of a vapor chamber 64 that can be incorporated into the power electronic module assembly 60. In one non-limiting embodiment, the vapor chamber 64 is designed to provide an effective thermal conductivity of at least 50 W/cmK.

The vapor chamber 64 may include a heat transfer medium 70 that includes a liquid phase 70-L and a vapor phase 70-V. Heat H from the heat source device 62 is dissipated through the substrate 66 and into the vapor chamber 64. As the heat H is absorbed, the liquid phase 70-L of the heat transfer medium 70 is vaporized into the vapor phase 70-V, thereby absorbing thermal energy. A wick 74 may be disposed inside the vapor chamber 64 for exerting a pressure on the liquid phase 70-L of the heat transfer medium 70. In one embodiment, the wick 74 includes a sintered metal powder or other suitable material capable of exerting capillary pressure on the liquid phase 70-L of the heat transfer medium 70.

The vaporized heat transfer medium 70-V circulates inside the vapor chamber 64 to dissipate the heat H away from the heat source device 62. The vaporized heat transfer medium 70-V may migrate toward a lower temperature portion of the vapor chamber 64, such as toward the second surface 78. The vaporized heat transfer medium 70-V is circulated within the vapor chamber 64 until it condenses back into its liquid phase 70-L, thereby releasing the absorbed heat into the cooling feature 68. The fluid F (see FIG. 2) may flow across the cooling feature 68 to remove heat from the vapor chamber 64. The liquid phase 70-L of the heat transfer medium 70 is then reabsorbed by the wick 74 and flows back toward a higher temperature portion of the vapor chamber 64, such as toward the first surface 76. It is considered within the scope of this disclosure that the vapor chamber 64 could include additional features that are not shown by this embodiment.

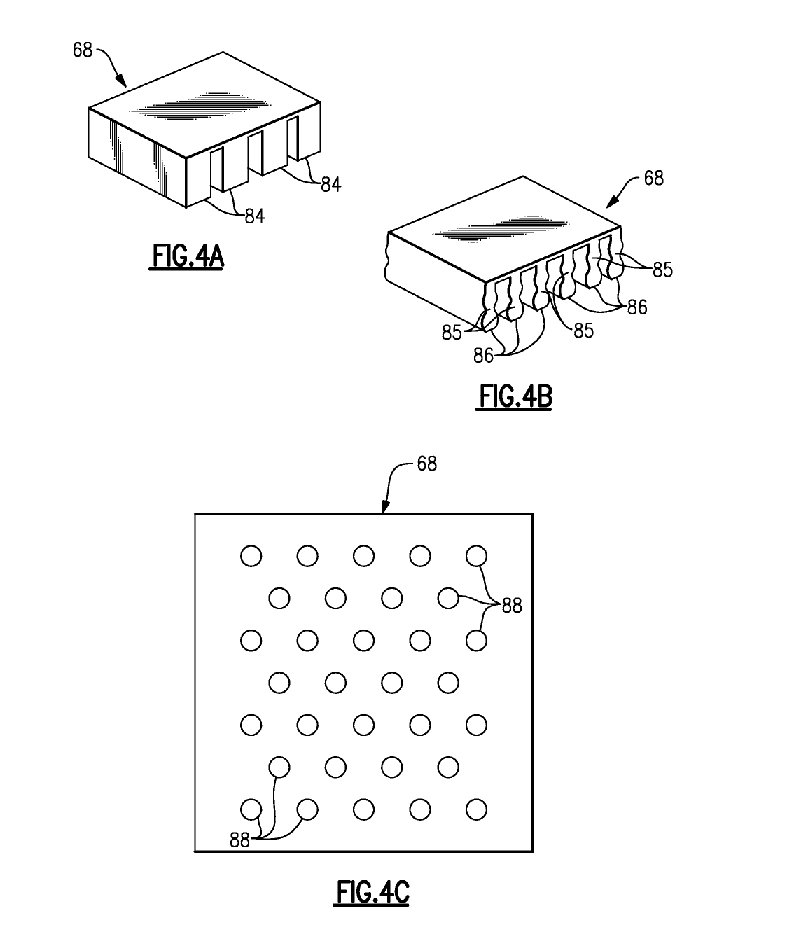

FIGS. 4A, 4B and 4C illustrate various embodiments of a cooling feature 68 that may be integrated with a vapor chamber of a power electronic module assembly as described above. Referring to FIG. 3A, the cooling feature 68 may include a plurality of fins 84. In another embodiment, as shown in FIG. 3B, the cooling feature 68 includes wavy fins 86. Each wavy fin 86 may include one or more undulations 85 for increasing the heat transfer effect provided by the cooling feature 68. The cooling feature 68 may alternatively include a plurality of pins 88 as shown in FIG. 4C. Other cooling feature designs and configurations are additionally contemplated as within the scope of this disclosure.

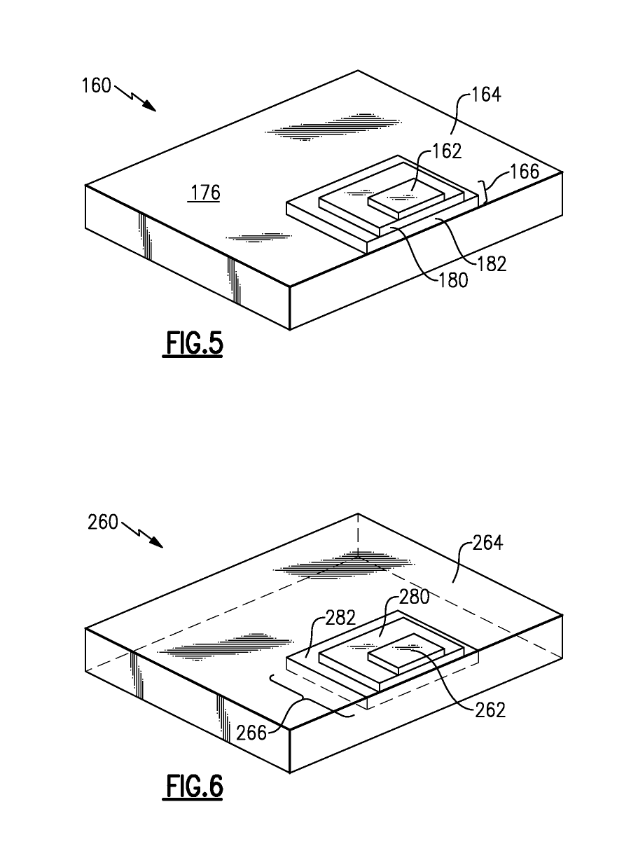

FIG. 5 illustrates another power electronic module assembly 160. In this disclosure, like reference numerals designate like elements where appropriate and reference numerals with the addition of 100 or multiples thereof designate modified elements that are understood to incorporate the same features and benefits of the corresponding original elements. This view is a highly schematic, cut-away view and may only illustrate portions of a power electronic module assembly. In other words, the power electronic module assembly 160 may include additional components, connectors and/or features than are shown in FIG. 5, and this disclosure is not limited to the specific configuration shown.

In this embodiment, the power electronic module assembly 160 includes a substrate 166 that is integrated with a vapor chamber 164 through direct deposition. The substrate 166 can be direct deposited on a first surface 176 of the vapor chamber 164. A heat source device 162, such as a semiconductor device, may be attached to the substrate 166 on an opposite side from the vapor chamber 164.

Direct deposition refers to methods in which a single or successive set of layers are deposited on a surface. The deposited layers can be shaped using masks or fixtures to limit the exposure of the deposited material onto the target surface. The area and thickness of the deposited layer may depend on the mask/fixture as well as incremental and/or post-deposition processing (e.g. temperature annealing). Non-limiting examples of direct deposition processes include, but are not limited to, metal ink deposition, sintering, active metal brazing, metal printing, chemical vapor deposition, sputter deposition, electro- or electroless-plating, atomic layer deposition, etc.

In one embodiment, the substrate 166 is an insulated metal substrate (IMS) that includes a single metal layer 180 and a single dielectric layer 182. In other words, a bottom metal layer of the substrate 166 between the dielectric layer 182 and the first surface 176 of the vapor chamber 164 may be eliminated by direct deposition of the substrate 166 onto the first surface 176. Although not shown, a cooling feature similar to those shown in FIGS. 4A, 4B and 4C can be integrated with the vapor chamber 164 to provide additional heat transfer capabilities.

FIG. 6 illustrates yet another exemplary power electronic module assembly 260. Like the previous embodiments, this view is a highly schematic, cut-away view and may only illustrate portions of a power electronic module assembly. In other words, the power electronic module assembly 260 may include additional components, connectors and/or features than are shown in FIG. 6, and this disclosure is not limited to the specific configuration shown.

In this embodiment, the power electronic module assembly 260 includes a substrate 266 integrated directly into (i.e., inside of) a vapor chamber 264. The substrate 266 may include a single metal layer 280 and a single dielectric layer 282.

In one embodiment, the vapor chamber 264 at least partially envelops the substrate 266. In another embodiment, the substrate 266 is integrated completely inside of the vapor chamber 264. Such configurations substantially reduce the vertical footprint of the power electronic module assembly 260.

A heat source device 262 is mounted to the substrate 266. The heat source device 262 may extend at least partially inside of the vapor chamber 264, in one embodiment. Although not shown, a cooling feature similar to those shown in FIGS. 4A, 4B and 4C can be integrated with the vapor chamber 264 to provide additional heat transfer capabilities.

Although the different non-limiting embodiments are illustrated as having specific components or steps, the embodiments of this disclosure are not limited to those particular combinations. It is possible to use some of the components or features from any of the non-limiting embodiments in combination with features or components from any of the other non-limiting embodiments.

It should be understood that like reference numerals identify corresponding or similar elements throughout the several drawings. It should be understood that although a particular component arrangement is disclosed and illustrated in these exemplary embodiments, other arrangements could also benefit from the teachings of this disclosure.

The foregoing description shall be interpreted as illustrative and not in any limiting sense. A worker of ordinary skill in the art would understand that certain modifications could come within the scope of this disclosure. For these reasons, the following claims should be studied to determine the true scope and content of this disclosure.

What is claimed is:

1. A power electronic module assembly, comprising:
a vapor chamber;
a substrate integrated with a first surface of said vapor chamber; and
at least one cooling feature integrated with a second surface of said vapor chamber.

2. The assembly as recited in claim 1, wherein said power electronic module assembly excludes bonding or interface layers between said vapor chamber and each of said substrate and said at least one cooling feature.

3. The assembly as recited in claim 1, wherein said substrate is an insulated metal substrate (IMS).

4. The assembly as recited in claim 1, wherein said substrate includes at least one metal layer and at least one dielectric layer.

5. The assembly as recited in claim 1, wherein said first surface is a top surface of said vapor chamber and said second surface is a bottom surface of said vapor chamber.

6. The assembly as recited in claim 1, comprising a heat source device mounted to said substrate.

7. The assembly as recited in claim 1, wherein said substrate is direct bonded to said first surface.

8. The assembly as recited in claim 1, wherein said substrate is integrated onto said first surface by direct deposition.

9. The assembly as recited in claim 1, wherein said substrate is integrated at least partially inside of said vapor chamber.

10. The assembly as recited in claim 1, wherein said at least one cooling feature includes fins or pins.

11. A vehicle, comprising:
a controller; and
a power electronic module assembly housed by said controller and having a vapor chamber and a substrate integrated with said vapor chamber.

12. The vehicle as recited in claim 11, wherein said controller is an inverter system controller.

13. The vehicle as recited in claim 11, wherein said controller is a converter system controller.

14. The vehicle as recited in claim 11, wherein said controller is an inverter system controller combined with a variable voltage converter.

15. The vehicle as recited in claim 11, comprising a cooling feature integrated with said vapor chamber opposite from said substrate.

16. A method for providing a highly integrated power electronic module assembly, comprising:
employing a vapor chamber;
integrating a substrate with a first surface of the vapor chamber.

17. The method as recited in claim 16, wherein the step of integrating includes:
direct bonding the substrate on the first surface.

18. The method as recited in claim 16, wherein the step of integrating includes:
direct depositing the substrate on the first surface.

19. The method as recited in claim 16, wherein the step of integrating includes:
enveloping the substrate at least partially inside the vapor chamber.

20. The method as recited in claim 16, comprising the step of:
integrating at least one cooling feature onto a second surface of the vapor chamber.
